(19) United States
(12) Patent Application Publication
(10) Pub. No.: US 2017/0018228 A1
(43) Pub. Date: Jan. 19, 2017

(54) Organic Light-Emitting Display Device and Scan Driving Circuit Thereof

(71) Applicant: EverDisplay Optronics (Shanghai) Limited, Shanghai (CN)

(72) Inventor: Jiangang Wang, Shanghai (CN)

(73) Assignee: EverDisplay Optronics (Shanghai) Ltd.

(21) Appl. No.: 14/990,496

(22) Filed: Jan. 7, 2016

(30) Foreign Application Priority Data
Jul. 16, 2015 (CN) 201510416992.0

(51) Int. Cl. G09G 3/3258

(52) U.S. Cl. CPC G09G 3/3258; G09G 2310/08; G09G 2300/0426

(57) ABSTRACT

A scan driving circuit includes a plurality of shift register units in cascade connection with each other. Each shift register unit includes a signal input end for receiving a first clock signal, a second clock signal, and an input signal. Each shift register unit further includes a signal output end for outputting an output signal. The output signal of one of the shift register units of a previous stage serves as the input signal of another shift register unit of a next stage. Each shift register unit adjusts an effective time length of the output signal by using duty cycles of the first clock signal and the second clock signal. An organic light-emitting display device includes an array substrate. The array substrate includes a pixel unit array, a data driving circuit, the scan driving circuit, at least one data line, and at least one scan line.

### BACKGROUND OF THE INVENTION

The present invention relates to a scan driving circuit for a display device and, more particularly, to an organic light-emitting display device and a scan driving circuit for the organic light-emitting display device.

Flat display panels (FDPs) perform better and is smaller and lighter than display devices using a cathode ray tube (CRT). Many researches on flat display panels have been conducted in recent years. Consequently, liquid crystal displays (LCDs), field emission displays (FEDs), plasma display panels (PDPs), and organic light-emitting diode (OLED) displays have been developed and used. Among these flat display panels, plasma display panels have a large screen, low luminance, and high power consumption due to low emitting efficiency, while the liquid crystal displays have a slow response speed and a high power consumption due to the use of backlight.

Organic light-emitting display devices uses OLEDs as the light source. However, overlapping of adjacent scan signals both at a low level exist in the scan driving circuits of the organic light-emitting display devices, adversely affecting the display effect.

### BRIEF SUMMARY OF THE INVENTION

The technical problem is fixed by the present invention providing an organic light-emitting display device and a scan driving circuit to effectively avoid the overlapping of adjacent scan signals both at a low level, assuring the display effect.

The above technical problem is fixed by the following technical solution of the present invention. In an aspect, the present invention includes a scan driving circuit for an organic light-emitting display device. The scan driving circuit includes a plurality of shift register units in cascade connection with each other. Each of the plurality of shift register units includes a signal input end for receiving a first clock signal, a second clock signal, and an input signal. Each of the plurality of shift register units further includes a signal output end for outputting an output signal. The output signal of one of the plurality of shift register units of a previous stage serves as the input signal of another of the plurality of shift register units of a next stage. Each of the plurality of shift register units adjusts an effective time length of the output signal by using duty cycles of the first clock signal and the second clock signal.

Each of the plurality of shift register units can provide a high-level voltage and a low-level voltage and include a first thin film transistor, a second thin film transistor, a third thin film transistor, a fourth thin film transistor, a fifth thin film transistor, a sixth thin film transistor, a first capacitor, and a second capacitor.

In a first example, a gate of the first thin film transistor is connected to the first clock signal. A first electrode of the first thin film transistor is connected to a first end of the first capacitor and a first electrode of the fourth thin film transistor and is then connected to the high-level voltage. A second electrode of the first thin film transistor is connected to a first electrode of the second thin film transistor. A second end of the first capacitor is connected to a second electrode of the second thin film transistor, a gate of the fourth thin film transistor, and a first electrode of the third thin film transistor. A gate of the third thin film transistor is connected to the second clock signal. A second electrode of the third thin film transistor is connected to the low-level voltage. A second electrode of the fourth thin film transistor is connected to a first electrode of the fifth thin film transistor. A second electrode of the fifth thin film transistor is connected to the first clock signal. A gate of the fifth thin film transistor is connected to a gate of the second thin film transistor and a first electrode of the sixth thin film transistor. A gate of the sixth thin film transistor is connected to the second clock signal. A second electrode of the sixth thin film transistor is connected to the input signal. A gate of the fifth thin film transistor and the first electrode of the sixth thin film transistor are connected to a second end of the second capacitor. A first end of the second capacitor, a second electrode of the fourth thin film transistor, and a first electrode of the fifth thin film transistor are connected to the output signal.

Each of the plurality of shifter register units can include a triggering module and a reset module. The triggering module provides the high-level voltage, the low-level voltage, the first clock signal, and the second clock signal and includes the first thin film transistor, the second thin film transistor, the third thin film transistor, and the first capacitor. The reset module provides the first clock signal and the second clock signal and includes the fifth thin film transistor, the sixth thin film transistor, and the second capacitor.

In a second example, a first electrode of the second thin film transistor is connected to a first end of the first capacitor and a first electrode of the fourth thin film transistor and is then connected to the high-level voltage. A second electrode of the second thin film transistor is connected to a first electrode of the first thin film transistor. A gate of the first thin film transistor is connected to the first clock signal. A second end of the first capacitor is connected to a second electrode of the first thin film transistor, a gate of the fourth thin film transistor, and a first electrode of the third thin film transistor. A gate of the third thin film transistor is connected to the second clock signal. A second electrode of the third thin film transistor is connected to the low-level voltage. A second electrode of the fourth thin film transistor is connected to a first electrode of the fifth thin film transistor. A second electrode of the fifth thin film transistor is connected to the first clock signal. A gate of the fifth thin film transistor is connected to a gate of the second thin film transistor and a first electrode of the sixth thin film transistor. A gate of the sixth thin film transistor is connected to the second clock signal. A second electrode of the sixth thin film transistor is connected to the input signal. A gate of the fifth thin film transistor and the first electrode of the sixth thin film transistor are connected to a second end of the second capacitor. A first end of the second capacitor, a second electrode of the fourth thin film transistor, and a first electrode of the fifth thin film transistor are connected to the output signal.

In a third example, a gate of the second thin film transistor is connected to the first clock signal. A first electrode of the second thin film transistor is connected to a first end of the first capacitor and a first electrode of the fourth thin film transistor and is then connected to the high-level voltage. A second electrode of the second thin film transistor is connected to a first electrode of the first thin film transistor. A second end of the first capacitor is connected to a second electrode of the first thin film transistor, a gate of the fourth thin film transistor, and a first electrode of the third thin film transistor. A gate of the third thin film transistor is connected to the second clock signal. A second electrode of the third thin film transistor is connected to the low-level voltage. A second electrode of the fourth thin film transistor is connected to a first electrode of the fifth thin film transistor. A second electrode of the fifth thin film transistor is connected to the first clock signal. A gate of the fifth thin film transistor is connected to a gate of the first thin film transistor and a first electrode of the sixth thin film transistor. A gate of the sixth thin film transistor is connected to the second clock signal. A second electrode of the sixth thin film transistor is connected to the input signal. A gate of the fifth thin film transistor and the first electrode of the sixth thin film transistor are connected to a first end of the second capacitor. A second end of the second capacitor is connected to the high-level voltage. A second electrode of the fourth thin film transistor and a first electrode of the fifth thin film transistor are connected to the output signal.

Each of the first, second, third, fourth, fifth, and sixth thin film transistors can be a P-type thin film transistor. Each of the first capacitor and the second capacitor can be a parasitic capacitor.

In a second aspect, the present invention provides an organic light-emitting display device including an array substrate. The array substrate includes a pixel unit array, a data driving circuit, a scan driving circuit, at least one data line, and at least one scan line. The scan driving circuit includes a plurality of shift register units in cascade connection with each other. Each of the plurality of shift register units includes a signal input end for receiving a first clock signal, a second clock signal, and an input signal. Each of the plurality of shift register units further includes a signal output end for outputting an output signal. The output signal of one of the plurality of shift register units of a previous stage serves as the input signal of another of the plurality of shift register units of a next stage. Each of the plurality of shift register units adjusts an effective time length of the output signal by using duty cycles of the first clock signal and the second clock signal.

The effect of the present invention is that the signal can be transmitted row by row, such that each row of pixels can sequentially be opened and such that the data signal can sequentially written into the display unit to achieve the function of displaying the screen.

The present invention will become clearer in light of the following detailed description of illustrative embodiments of this invention described in connection with the drawings.

### DESCRIPTION OF THE DRAWINGS

FIG. 1 is a diagrammatic view of a structure of an organic light-emitting display device according to the present invention.

FIG. 2 is a diagrammatic view of a structure for driving a pixel unit according to the present invention.

FIG. 3 is a waveform diagram required by the organic light-emitting display device according to the present invention.

FIG. 4 is a diagrammatic view of a scan driving circuit of the organic light-emitting display device according to the present invention.

FIG. 5 is a diagrammatic view of a circuitry of a first example of a shift register unit of the scan driving circuit according to the present invention.

FIG. 6 is a timing sequence of the first example of the shift register unit of the scan driving circuit according to the present invention.

FIG. 7 is a diagrammatic view illustrating a first movement of a shift register unit of the scan driving circuit according to the present invention.

FIG. 8 is a diagrammatic view illustrating a second movement of a shift register unit of the scan driving circuit according to the present invention.

FIG. 9 is a diagrammatic view illustrating a third movement of a shift register unit of the scan driving circuit according to the present invention.

FIG. 10 is a diagrammatic view of a circuitry of a second example of the shift register unit of the scan driving circuit according to the present invention.

FIG. 11 is a diagrammatic view of a circuitry of a third example of the shift register unit of the scan driving circuit according to the present invention.

### DETAILED DESCRIPTION OF THE INVENTION

Other advantages and effects of the present invention can easily be appreciated by one skilled in the art from the contents disclosed in the specification by way of certain examples illustrating the embodiments for practicing the present invention. Nevertheless, the present invention can be embodied or applied by other practice. Various modifications or changes can be made to the details of the specification in view of different aspects and applications without departing from the spirit of the present invention.

It is noted that the figures of the embodiments are drawn for ease of explanation of the basic concepts of the present invention only. The components illustrated in the figures are related to the present invention, but they are not drawn according to the number, shapes, and sizes of the components according to actual practice. The pattern, number, and proportion of the components can be varied according to needs in actual practice, and the layout patterns of the components could be more complicated.

The present invention will be described further in connection with the accompanying drawings and specific embodiments.

The organic light-emitting display device according to the present invention includes an array substrate. The array substrate can include a pixel unit array, a data driving circuit, a scan driving circuit, at least one data line, and at least one scan line.

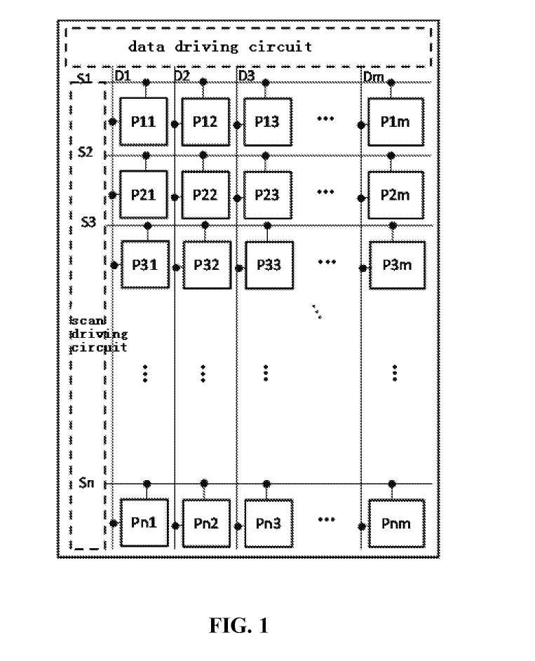

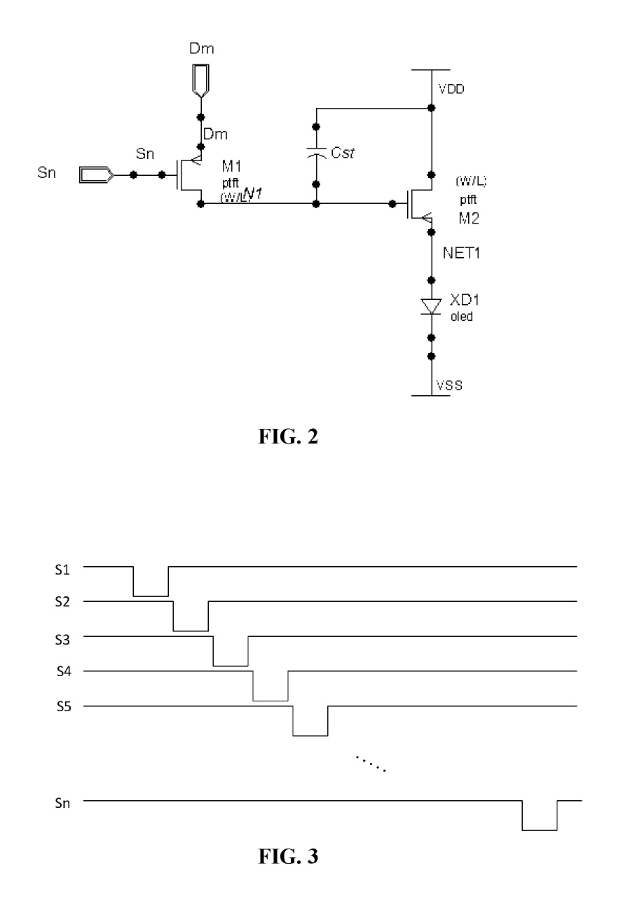

In an example shown in FIG. 1, the organic light-emitting display device includes a data driving circuit, a scan driving circuit, a plurality of data lines D1-Dm, a plurality of scan lines S1-Sn, and a pixel section. A pixel unit array in the pixel section is comprised of a plurality of pixel units P11-Pnm. Driving a pixel unit requires at least a data signal and a scan signal. As an example, driving the pixel unit Pnm requires the data signal Dm and the scan signal Sn.

When it is desired to display the screen, the organic light-emitting display device has to open each row of pixel units in sequence. Considering the RC delay of the scan signals during manufacture, a certain period of time is required between opening of one of two adjacent rows of pixel units and opening of the other of the two adjacent rows of pixel units to avoid the screen from abnormal phenomenon. As an example, a waveform diagram required by a P-type thin film transistor is shown in FIG. 3.

The present invention provides the scan driving device for the organic light-emitting display device. The scan driving device includes a plurality of shift register units in cascade connection with each other. Each shift register unit includes a signal input end for receiving a first clock signal, a second clock signal, and an input signal. Each shift register unit further includes a signal output end for outputting an output signal. The output signal of one of the shift register units of a previous stage serves as the input signal of another shift register unit of a next stage. Each shift register unit adjusts an effective time length of the output signal by using duty cycles of the first clock signal and the second clock signal.

Specifically, the present invention utilizes two clock signals (the first clock signal CK1 and the second clock signal CK2), a high-level voltage VDD, thin film transistors (a first thin film transistor T1, a second thin film transistor T2, a third thin film transistor T3, a fourth thin film transistor T4, a fifth thin film transistor T5, a sixth thin film transistor T6), two capacitors (a first capacitor C1 and a second capacitor C2), and a low-level voltage VEE to form a shift register unit.

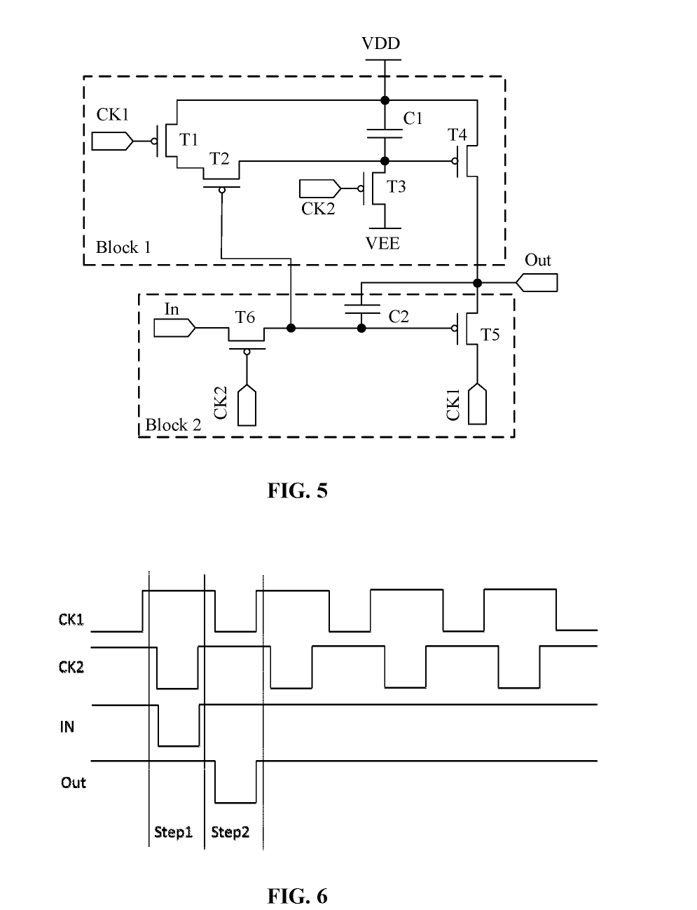

FIG. 5 is a diagrammatic view of a circuitry of a first example of the shift register unit of the scan driving circuit according to the present invention. As shown in FIG. 5, a gate of the first thin film transistor T1 is connected to the first clock signal CK1. A first electrode of the first thin film transistor T1 is connected to a first end of the first capacitor C1 and a first electrode of the fourth thin film transistor T4 and is then connected to the high-level voltage VDD. A second electrode of the first thin film transistor T1 is connected to a first electrode of the second thin film transistor T2. A second end of the first capacitor C1 is connected to a second electrode of the second thin film transistor T2, a gate of the fourth thin film transistor T4, and a first electrode of the third thin film transistor T3. A gate of the third thin film transistor T3 is connected to the second clock signal CK2. A second electrode of the third thin film transistor T3 is connected to the low-level voltage VEE. A second electrode of the fourth thin film transistor T4 is connected to a first electrode of the fifth thin film transistor T5. A second electrode of the fifth thin film transistor T5 is connected to the first clock signal CK1. A gate of the fifth thin film transistor T5 is connected to a gate of the second thin film transistor T2 and a first electrode of the sixth thin film transistor T6. A gate of the sixth thin film transistor T6 is connected to the second clock signal CK2. A second electrode of the sixth thin film transistor T6 is connected to the input signal IN. A gate of the fifth thin film transistor T5 and the first electrode of the sixth thin film transistor T6 are connected to a second end of the second capacitor C2. A first end of the second capacitor C2, a second electrode of the fourth thin film transistor T4, and a first electrode of the fifth thin film transistor T5 are connected to the output signal Out.

As shown in FIG. 5, each shifter register unit includes a triggering module Block1 and a reset module Block2. The high-level voltage VDD, the first clock signal CK1, the second clock signal CK2, the first thin film transistor T1, the second thin film transistor T2, the third thin film transistor T3, the first capacitor C1, and the low-level voltage VEE form the triggering module Block1. The first clock signal CK1, the second clock signal CK2, the fifth thin film transistor T5, the sixth thin film transistor T6, and the second capacitor C2 form the reset module Block2. The reset module Block2 is responsible for triggering. When the input signal IN is low, the triggering is done. The triggering module Block1 is responsible for resetting after triggering. After the reset module Block2 has done the triggering, the triggering module Block1 resets when the next clock signal arrives, thereby forming the next shift register unit.

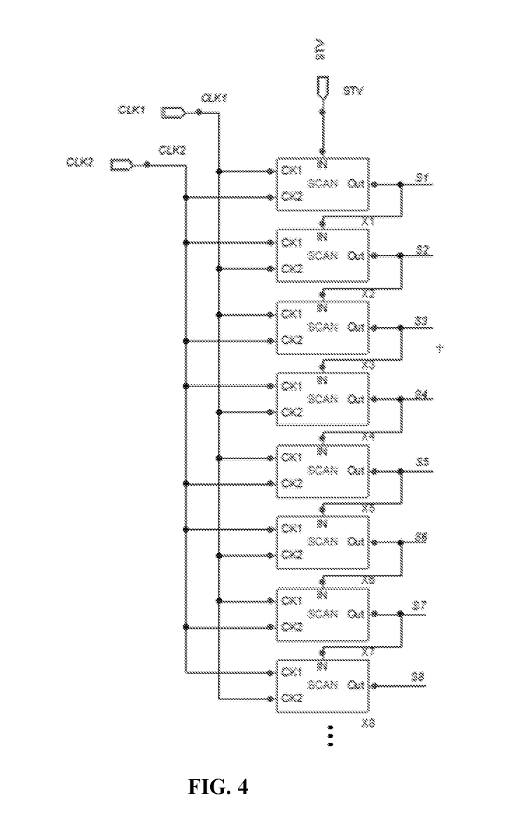

A scan driving circuit of the organic light-emitting display device can be formed by cascading a plurality of shift register units, as shown in FIG. 4. Each shift register unit utilizes the first clock signal CK1, the second clock signal CK2, the input signal IN, and the output signal Out. The output signal Out of the shift register unit of the previous stage serves as the input signal IN of the shift register unit of the next stage. The duty cycles of the first clock signal CK1 and the second clock signal CK2 are used to adjust the effective time length of the output signal, effectively eliminating the overlapping when both of two adjacent scan signals are at a low level.

FIG. 6 shows the waveforms of the clock signals and the start signals desired by the present invention. The working principle of the present invention will now be described.

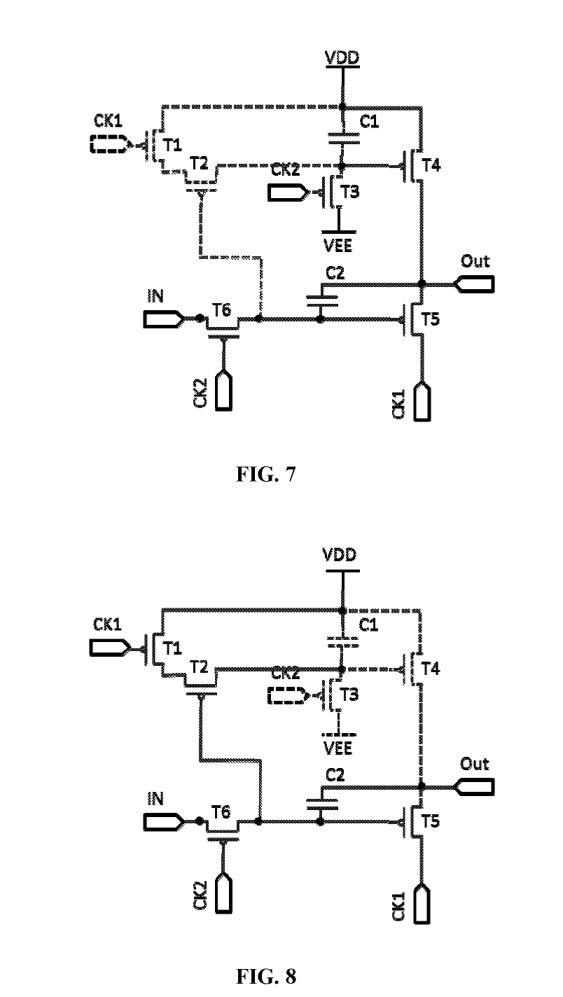

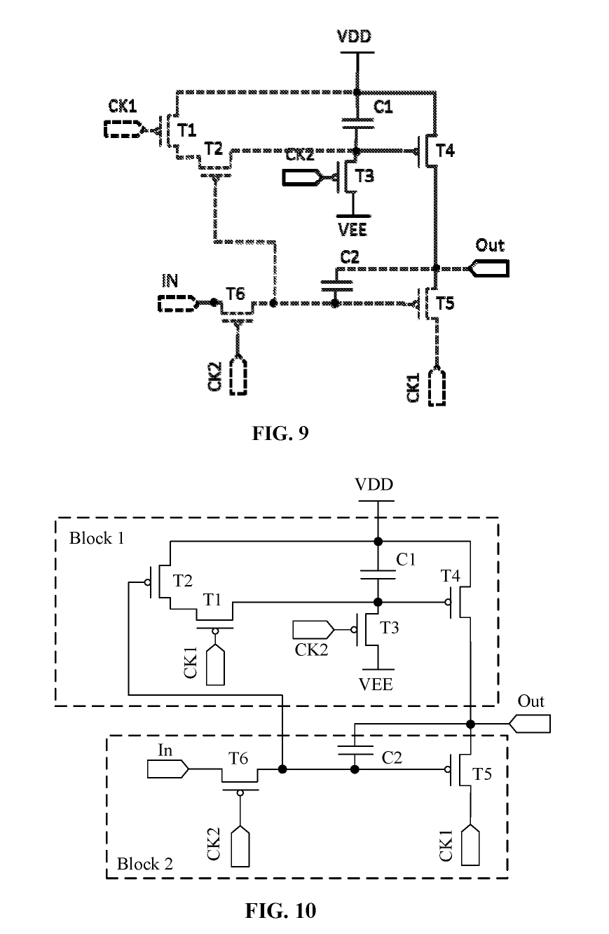

In a first stage Step1, the second clock signal CK2 is low, the first clock signal CK1 is high, the fourth thin film transistor T4 is open, and the second capacitor C2 stores the status of the input signal IN. When the input signal IN is low, as shown in FIG. 7, the fourth thin film transistor T4 and the fifth thin film transistor T5 are open, and the output status of the output signal Out is high. On the other hand, when the input signal IN is high, the fourth thin film transistor T4 is open, and the fifth thin film transistor T5 is closed, as shown in FIG. 9, and the output status of the output signal Out is the same as the high-level voltage VDD.

In a second stage Step2, the second clock signal CK2 is high, and the first clock signal CK1 is low. When the last status of the input signal IN is low, as shown in FIG. 8, the first thin film transistor T1 and the second thin film transistor T2 are open, the first capacitor C1 is initialized to be high, the fourth thin film transistor T4 is open, the fifth thin film transistor T5 is closed, and both of the output statuses of the output signal Out and the first clock signal CK1 are low. On the other hand, when the last status of the input signal IN is high, as shown in FIG. 9, the second clock signal CK2 is initialized to be high, the fifth thin film transistor T5 is closed, the fourth thin film transistor T4 is open, and the output of the output signal Out is high.

During operation of the circuitry, the duty cycles of the first clock signal CK1 and the second clock signal CK2 can be used to adjust the effective time length of the output signal. The signal can be transmitted row by row, such that each row of pixels can sequentially be opened and such that the data signal can sequentially written into the display unit to achieve the function of displaying the screen, thereby effectively eliminating the overlapping when both of two adjacent scan signals are at a low level.

FIG. 10 is a diagrammatic view of a circuitry of a second example of the shift register unit of the scan driving circuit according to the present invention. As shown in FIG. 10, in comparison with the first embodiment shown in FIG. 5, the positions of the first thin film transistor T1 and the second thin film transistor T2 in the triggering module Block1 are switched. The main differences are that a first electrode of the second thin film transistor T2 is connected to a first end of the first capacitor C1 and a first electrode of the fourth thin film transistor T4 and is then connected to the high-level voltage VDD; a second electrode of the second thin film transistor T2 is connected to a first electrode of the first thin film transistor T1; and a second end of the first capacitor C1 is connected to a second electrode of the first thin film transistor T1, a gate of the fourth thin film transistor T4, and a first electrode of the third thin film transistor T3.

Specifically, the first electrode of the second thin film transistor T2 is connected to the first end of the first capacitor C1 and the first electrode of the fourth thin film transistor T4 and is then connected to the high-level voltage VDD. The second electrode of the second thin film transistor T2 is connected to the first electrode of the first thin film transistor T1. A gate of the first thin film transistor T1 is connected to the first clock signal CK1. A second end of the first capacitor C1 is connected to a second electrode of the first thin film transistor T1, a gate of the fourth thin film transistor T4, and a first electrode of the third thin film transistor T3. A gate of the third thin film transistor T3 is connected to the second clock signal CK2. A second electrode of the third thin film transistor T3 is connected to the low-level voltage VEE. A second electrode of the fourth thin film transistor T4 is connected to a first electrode of the fifth thin film transistor T5. A second electrode of the fifth thin film transistor T5 is connected to the first clock signal CK1. A gate of the fifth thin film transistor T5 is connected to a gate of the second thin film transistor T2 and a first electrode of the sixth thin film transistor T6. A gate of the sixth thin film transistor T6 is connected to the second clock signal CK2. A second electrode of the sixth thin film transistor T6 is connected to the input signal IN. A gate of the fifth thin film transistor T5 and the first electrode of the sixth thin film transistor T6 are connected to a second end of the second capacitor C2. The first end of the second capacitor C2, the second electrode of the fourth thin film transistor T4, and the first electrode of the fifth thin film transistor T5 are connected to the output signal Out.

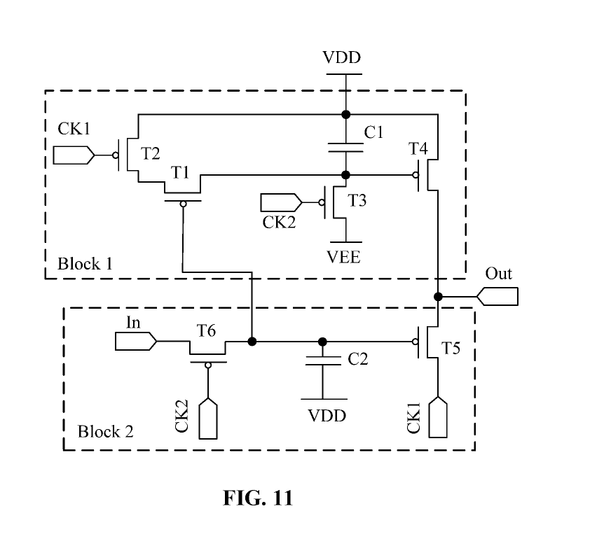

FIG. 11 is a diagrammatic view of a circuitry of a third example of the shift register unit of the scan driving circuit according to the present invention. In this embodiment, the reset module Block2 changes the connection of the second capacitor C2. Namely, the gate of the fifth thin film transistor T5 and the first electrode of the sixth thin film transistor T6 are connected to the first end of the second capacitor C2; a second end of the second capacitor C2 is connected to the high-level voltage VDD; and a second electrode of the fourth thin film transistor T4 and a first electrode of the fifth thin film transistor T5 are connected to the output signal Out.

Specifically, a gate of the second thin film transistor T2 is connected to the first clock signal CK1. A first electrode of the second thin film transistor T2 is connected to a first end of the first capacitor C1 and a first electrode of the fourth thin film transistor T4 and is then connected to the high-level voltage VDD. A second electrode of the second thin film transistor T2 is connected to a first electrode of the first thin film transistor T1. A second end of the first capacitor C1 is connected to a second electrode of the first thin film transistor T1, a gate of the fourth thin film transistor T4, and a first electrode of the third thin film transistor T3. A gate of the third thin film transistor T3 is connected to the second clock signal CK2. A second electrode of the third thin film transistor T3 is connected to the low-level voltage VEE. A second electrode of the fourth thin film transistor T4 is connected to a first electrode of the fifth thin film transistor T5. A second electrode of the fifth thin film transistor T5 is connected to the first clock signal CK1. A gate of the fifth thin film transistor T5 is connected to a gate of the first thin film transistor T1 and a first electrode of the sixth thin film transistor T6. A gate of the sixth thin film transistor T6 is connected to the second clock signal CK2. A second electrode of the sixth thin film transistor T6 is connected to the input signal IN. The gate of the fifth thin film transistor T5 and the first electrode of the sixth thin film transistor T6 are connected to the first end of the second capacitor C2. The second end of the second capacitor C2 is connected to the high-level voltage VDD. The second electrode of the fourth thin film transistor T4 and a first electrode of the fifth thin film transistor T5 are connected to the output signal Out.

Each of the first, second, third, fourth, fifth, and sixth thin film transistors T1-T6 can be a P-type thin film transistor. Each of the first capacitor C1 and the second capacitor C2 is a parasitic capacitor.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. A scan driving circuit for an organic light-emitting display device, comprising a plurality of shift register units in cascade connection with each other, with each of the plurality of shift register units including a signal input end for receiving a first clock signal, a second clock signal, and an input signal, with each of the plurality of shift register units further including a signal output end for outputting an output signal, and with the output signal of one of the plurality of shift register units of a previous stage serving as the input signal of another of the plurality of shift register units of a next stage, wherein each of the plurality of shift register units adjusts an effective time length of the output signal by using duty cycles of the first clock signal and the second clock signal.

2. The scan driving circuit for an organic light-emitting display device as claimed in claim 1, with each of the plurality of shift register units providing a high-level voltage and a low-level voltage and including a first thin film transistor, a second thin film transistor, a third thin film transistor, a fourth thin film transistor, a fifth thin film transistor, a sixth thin film transistor, a first capacitor, and a second capacitor, with a gate of the first thin film transistor connected to the first clock signal, with a first electrode of the first thin film transistor connected to a first end of the first capacitor and a first electrode of the fourth thin film transistor and then connected to the high-level voltage, with a second electrode of the first thin film transistor connected to a first electrode of the second thin film transistor, with a second end of the first capacitor connected to a second electrode of the second thin film transistor, a gate of the fourth thin film transistor, and a first electrode of the third thin film transistor, with a gate of the third thin film transistor connected to the second clock signal, with a second electrode of the third thin film transistor connected to the low-level voltage, with a second electrode of the fourth thin film transistor connected to a first electrode of the fifth thin film transistor, with a second electrode of the fifth thin film transistor connected to the first clock signal, with a gate of the fifth thin film transistor connected to a gate of the second thin film transistor and a first electrode of the sixth thin film transistor, with a gate of the sixth thin film transistor connected to the second clock signal, with a second electrode of the sixth thin film transistor connected to the input signal, with a gate of the fifth thin film transistor and the first electrode of the sixth thin film transistor connected to a second end of the second capacitor, and with a first end of the second capacitor, a second electrode of the fourth thin film transistor, and a first electrode of the fifth thin film transistor connected to the output signal.

3. The scan driving circuit for an organic light-emitting display device as claimed in claim 2, with each of the plurality of shifter register units including a triggering module and a reset module, with the triggering module providing the high-level voltage, the low-level voltage, the first clock signal, and the second clock signal and including the first thin film transistor, the second thin film transistor, the third thin film transistor, and the first capacitor, and with the reset module providing the first clock signal and the second clock signal and including the fifth thin film transistor, the sixth thin film transistor, and the second capacitor.

4. The scan driving circuit for an organic light-emitting display device as claimed in claim 2, wherein each of the first, second, third, fourth, fifth, and sixth thin film transistors is a P-type thin film transistor, and wherein each of the first capacitor and the second capacitor is a parasitic capacitor.

5. The scan driving circuit for an organic light-emitting display device as claimed in claim 1, with each of the plurality of shift register units providing a high-level voltage and a low-level voltage and including a first thin film transistor, a second thin film transistor, a third thin film transistor, a fourth thin film transistor, a fifth thin film transistor, a sixth thin film transistor, a first capacitor, and a second capacitor, with a first electrode of the second thin film transistor connected to a first end of the first capacitor and a first electrode of the fourth thin film transistor and then connected to the high-level voltage, with a second electrode of the second thin film transistor connected to a first electrode of the first thin film transistor, with a gate of the first thin film transistor connected to the first clock signal, with a second end of the first capacitor connected to a second electrode of the first thin film transistor, a gate of the fourth thin film transistor, and a first electrode of the third thin film transistor, with a gate of the third thin film transistor connected to the second clock signal, with a second electrode of the third thin film transistor connected to the low-level voltage, with a second electrode of the fourth thin film transistor connected to a first electrode of the fifth thin film transistor, with a second electrode of the fifth thin film transistor connected to the first clock signal, with a gate of the fifth thin film transistor connected to a gate of the second thin film transistor and a first electrode of the sixth thin film transistor, with a gate of the sixth thin film transistor connected to the second clock signal, with a second electrode of the sixth thin film transistor connected to the input signal, with a gate of the fifth thin film transistor and the first electrode of the sixth thin film transistor connected to a second end of the second capacitor, and with a first end of the second capacitor, a second electrode of the fourth thin film transistor, and a first electrode of the fifth thin film transistor connected to the output signal.

6. The scan driving circuit for an organic light-emitting display device as claimed in claim 5, wherein each of the first, second, third, fourth, fifth, and sixth thin film transistors is a P-type thin film transistor, and wherein each of the first capacitor and the second capacitor is a parasitic capacitor.

7. The scan driving circuit for an organic light-emitting display device as claimed in claim 1, with each of the plurality of shift register units providing a high-level voltage and a low-level voltage and including a first thin film transistor, a second thin film transistor, a third thin film transistor, a fourth thin film transistor, a fifth thin film transistor, a sixth thin film transistor, a first capacitor, and a second capacitor, with a gate of the second thin film transistor connected to the first clock signal, with a first electrode of the second thin film transistor connected to a first end of the first capacitor and a first electrode of the fourth thin film transistor and then connected to the high-level voltage, with a second electrode of the second thin film transistor connected to a first electrode of the first thin film transistor, with a second end of the first capacitor connected to a second electrode of the first thin film transistor, a gate of the fourth thin film transistor, and a first electrode of the third thin film transistor, with a gate of the third thin film transistor connected to the second clock signal, with a second electrode of the third thin film transistor connected to the low-level voltage, with a second electrode of the fourth thin film transistor connected to a first electrode of the fifth thin film transistor, with a second electrode of the fifth thin film transistor connected to the first clock signal, with a gate of the fifth thin film transistor connected to a gate of the first thin film transistor and a first electrode of the sixth thin film transistor, with a gate of the sixth thin film transistor connected to the second clock signal, with a second electrode of the sixth thin film transistor connected to the input signal, with a gate of the fifth thin film transistor and the first electrode of the sixth thin film transistor connected to a first end of the second capacitor, with a second end of the second capacitor connected to the high-level voltage, and with a second electrode of the fourth thin film transistor and a first electrode of the fifth thin film transistor connected to the output signal.

8. The scan driving circuit for an organic light-emitting display device as claimed in claim 7, wherein each of the first, second, third, fourth, fifth, and sixth thin film transistors is a P-type thin film transistor, and wherein each of the first capacitor and the second capacitor is a parasitic capacitor.

9. An organic light-emitting display device comprising an array substrate, with the array substrate including a pixel unit array, a data driving circuit, a scan driving circuit, at least one data line, and at least one scan line, with the scan driving circuit including a plurality of shift register units in cascade connection with each other, with each of the plurality of shift register units including a signal input end for receiving a first clock signal, a second clock signal, and an input signal, with each of the plurality of shift register units further including a signal output end for outputting an output signal, and with the output signal of one of the plurality of shift register units of a previous stage serving as the input signal of another of the plurality of shift register units of a next stage, wherein each of the plurality of shift register units adjusts an effective time length of the output signal by using duty cycles of the first clock signal and the second clock signal.

10. The scan driving circuit for an organic light-emitting display device as claimed in claim 9, with each of the plurality of shift register units providing a high-level voltage and a low-level voltage and including a first thin film transistor, a second thin film transistor, a third thin film transistor, a fourth thin film transistor, a fifth thin film transistor, a sixth thin film transistor, a first capacitor, and a second capacitor, with a gate of the first thin film transistor connected to the first clock signal, with a first electrode of the first thin film transistor connected to a first end of the first capacitor and a first electrode of the fourth thin film transistor and then connected to the high-level voltage, with a second electrode of the first thin film transistor connected to a first electrode of the second thin film transistor, with a second end of the first capacitor connected to a second electrode of the second thin film transistor, a gate of the fourth thin film transistor, and a first electrode of the third thin film transistor, with a gate of the third thin film transistor connected to the second clock signal, with a second electrode of the third thin film transistor connected to the low-level voltage, with a second electrode of the fourth thin film transistor connected to a first electrode of the fifth thin film transistor, with a second electrode of the fifth thin film transistor connected to the first clock signal, with a gate of the fifth thin film transistor connected to a gate of the second thin film transistor and a first electrode of the sixth thin film transistor, with a gate of the sixth thin film transistor connected to the second clock signal, with a second electrode of the sixth thin film transistor connected to the input signal, with a gate of the fifth thin film transistor and the first electrode of the sixth thin film transistor connected to a second end of the second capacitor, and with a first end of the second capacitor, a second electrode of the fourth thin film transistor, and a first electrode of the fifth thin film transistor connected to the output signal.

11. The organic light-emitting display device as claimed in claim 10, with each of the plurality of shifter register units including a triggering module and a reset module, with the triggering module providing the high-level voltage, the low-level voltage, the first clock signal, and the second clock signal and including the first thin film transistor, the second thin film transistor, the third thin film transistor, and the first capacitor, and with the reset module providing the first clock signal and the second clock signal and including the fifth thin film transistor, the sixth thin film transistor, and the second capacitor.

12. The organic light-emitting display device as claimed in claim 10, wherein each of the first, second, third, fourth, fifth, and sixth thin film transistors is a P-type thin film transistor, and wherein each of the first capacitor and the second capacitor is a parasitic capacitor.

13. The organic light-emitting display device as claimed in claim 9, with each of the plurality of shift register units providing a high-level voltage and a low-level voltage and including a first thin film transistor, a second thin film transistor, a third thin film transistor, a fourth thin film transistor, a fifth thin film transistor, a sixth thin film transistor, a first capacitor, and a second capacitor, with a first electrode of the second thin film transistor connected to a first end of the first capacitor and a first electrode of the fourth thin film transistor and then connected to the high-level voltage, with a second electrode of the second thin film transistor connected to a first electrode of the first thin film transistor, with a gate of the first thin film transistor connected to the first clock signal, with a second end of the first capacitor connected to a second electrode of the first thin film transistor, a gate of the fourth thin film transistor, and a first electrode of the third thin film transistor, with a gate of the third thin film transistor connected to the second clock signal, with a second electrode of the third thin film transistor connected to the low-level voltage, with a second electrode of the fourth thin film transistor connected to a first electrode of the fifth thin film transistor, with a second electrode of the fifth thin film transistor connected to the first clock signal, with a gate of the fifth thin film transistor connected to a gate of the second thin film transistor and a first electrode of the sixth thin film transistor, with a gate of the sixth thin film transistor connected to the second clock signal, with a second electrode of the sixth thin film transistor connected to the input signal, with a gate of the fifth thin film transistor and the first electrode of the sixth thin film transistor connected to a second end of the second capacitor, and with a first end of the second capacitor, a second electrode of the fourth thin film transistor, and a first electrode of the fifth thin film transistor connected to the output signal.

14. The organic light-emitting display device as claimed in claim 13, wherein each of the first, second, third, fourth, fifth, and sixth thin film transistors is a P-type thin film transistor, and wherein each of the first capacitor and the second capacitor is a parasitic capacitor.

15. The organic light-emitting display device as claimed in claim 9, with each of the plurality of shift register units providing a high-level voltage and a low-level voltage and including a first thin film transistor, a second thin film transistor, a third thin film transistor, a fourth thin film transistor, a fifth thin film transistor, a sixth thin film transistor, a first capacitor, and a second capacitor, with a gate of the second thin film transistor connected to the first clock signal, with a first electrode of the second thin film transistor connected to a first end of the first capacitor and a first electrode of the fourth thin film transistor and then connected to the high-level voltage, with a second electrode of the second thin film transistor connected to a first electrode of the first thin film transistor, with a second end of the first capacitor connected to a second electrode of the first thin film transistor, a gate of the fourth thin film transistor, and a first electrode of the third thin film transistor, with a gate of the third thin film transistor connected to the second clock signal, with a second electrode of the third thin film transistor connected to the low-level voltage, with a second electrode of the fourth thin film transistor connected to a first electrode of the fifth thin film transistor, with a second electrode of the fifth thin film transistor connected to the first clock signal, with a gate of the fifth thin film transistor connected to a gate of the first thin film transistor and a first electrode of the sixth thin film transistor, with a gate of the sixth thin film transistor connected to the second clock signal, with a second electrode of the sixth thin film transistor connected to the input signal, with a gate of the fifth thin film transistor and the first electrode of the sixth thin film transistor connected to a first end of the second capacitor, with a second end of the second capacitor connected to the high-level voltage, and with a second electrode of the fourth thin film transistor and a first electrode of the fifth thin film transistor connected to the output signal.

16. The organic light-emitting display device as claimed in claim 15, wherein each of the first, second, third, fourth, fifth, and sixth thin film transistors is a P-type thin film transistor, and wherein each of the first capacitor and the second capacitor is a parasitic capacitor.
